(19) United States
(12) Patent Application Publication
(10) Pub. No.: US 2015/0017372 A1
(43) Pub. Date: Jan. 15, 2015

(54) METHOD OF MANUFACTURING RESIN-ENCAPSULATED ELECTRONIC COMPONENT AND APPARATUS FOR MANUFACTURING RESIN-ENCAPSULATED ELECTRONIC COMPONENT

(71) Applicant: TOWA CORPORATION, Kyoto-shi, Kyoto (JP)

(72) Inventors: Hiroshi Uragami, Kyoto-shi (JP); Keita Mizuma, Kyoto-shi (JP); Ichitaro Okamoto, Kyoto-shi (JP); Naoki Takada, Kyoto-shi (JP); Mamoru Nakamura, Kyoto-shi (JP); Shinsuke Yasuda, Kyoto-shi (JP)

(73) Assignee: TOWA CORPORATION, Kyoto-shi, Kyoto (JP)

(21) Appl. No.: 14/381,887

(22) PCT Filed: Nov. 8, 2012
(86) PCT No.: PCT/JP2012/078996

§ 371 Date: Aug. 28, 2014

(30) Foreign Application Priority Data
Mar. 7, 2012 (JP) 2012-051057

(51) Int. Cl. H01L 21/56; H01L 21/67; B29C 43/18

(52) U.S. Cl. CPC H01L 21/565; B29C 43/18; H01L 21/67126; B29C 2043/181; B29L 2031/3481
USPC 428/41.8; 264/272.11; 425/515; 156/60; 428/457

(57) ABSTRACT

The present invention is to provide a method of manufacturing a resin-encapsulated electronic component and an apparatus for manufacturing a resin-encapsulated electronic component that enable the manufacture of a resin-encapsulated electronic component including a plate-like member in a simple manner at low cost. The method of manufacturing a resin-encapsulated electronic component, the resin-encapsulated electronic component including a plate-like member 13, the method includes: placing a resin 15 on the plate-like member 13; transferring the resin 15 to a position of a die cavity 17a of a molding die in a state where the resin 15 is placed on the plate-like member 13; and performing resin-encapsulation of an electronic component by subjecting the resin 15 to compression molding together with the plate-like member 13 and the electronic component in a state where the electronic component is soaked in the resin 15 placed on the plate-like member 13 in the die cavity 17a.

### TECHNICAL FIELD

The present invention relates to a method of manufacturing a resin-encapsulated electronic component and an apparatus for manufacturing a resin-encapsulated electronic component.

### BACKGROUND ART

Electronic components such as IC, semiconductor electronic components, and the like are mostly molded as resin-encapsulated electronic components to use. In this instance, there is a case where the electronic component is molded together with a plate-like member such as a heat-releasing plate (heat sink) for releasing heat generated by the electronic component for cooling or a shield (blocking plate) for blocking electromagnetic waves emitted from the electronic component. As the method of manufacturing a resin-encapsulated electronic component including such a plate-like member, for example, there is a method of attaching the plate-like member after performing resin-encapsulation of the electronic component by compression molding or the like. There is also a method of performing resin-encapsulation of the electronic component together with the plate-like member at the time of performing transfer molding in a molding die (metal die).

### DISCLOSURE OF THE INVENTION

### Problem to be Solved by the Invention

However, the method of attaching the plate-like member after performing resin-encapsulation has a problem in manufacturing efficiency that the method requires a number of steps because a resin-encapsulation step and a plate-like member attachment step are performed separately. Further, the method of performing resin-encapsulation of the electronic component together with the plate-like member by transfer molding needs to load a lead frame together with the electronic component and the plate-like member in a molding die. Therefore, the structure of the handler for transfer molding is complicated and the facility is costly.

Hence, the present invention is intended to provide a method of manufacturing a resin-encapsulated electronic component and an apparatus for manufacturing a resin-encapsulated electronic component that enable the manufacture of a resin-encapsulated electronic component including a plate-like member in a simple manner at low cost.

### Means for Solving Problem

In order to achieve the aforementioned purpose, the manufacturing method of the present invention is a method of manufacturing a resin-encapsulated electronic component, the resin-encapsulated electronic component including a plate-like member, the method includes placing a resin on the plate-like member, transferring the resin to a position of a die cavity of a molding die in a state where the resin is placed on the plate-like member, and performing resin-encapsulation of the electronic component by subjecting the resin to compression molding together with the plate-like member and the electronic component in a state where the electronic component is soaked in the resin placed on the plate-like member in the die cavity.

Further, the manufacturing apparatus of the present invention is an apparatus for manufacturing a resin-encapsulated electronic component, the resin-encapsulated electronic component including a plate-like member, the apparatus includes a resin placement unit, a molding die having a die cavity, a transfer unit, and a resin-encapsulation unit, wherein the resin placement unit places a resin on the plate-like member, wherein the transfer unit transfers the resin to a position of the die cavity in a state where the resin is placed on the plate-like member, and wherein the resin-encapsulation unit performs resin-encapsulation of the electronic component by subjecting the resin to compression molding together with the plate-like member and the electronic component in a state where the electronic component is soaked in the resin placed on the plate-like member in the die cavity.

### Effects of the Invention

According to the manufacturing method or the manufacturing apparatus of the present invention, a resin-encapsulated electronic component including a plate-like member can be manufactured in a simple manner at low cost.

### BRIEF DESCRIPTION OF DRAWINGS

FIGS. 1 (a) to (i) are cross sectional views schematically showing the resin placement step, the transfer step, and steps before and after these steps in Example 1.

FIG. 2 is a cross sectional view schematically showing a part of the manufacturing apparatus (apparatus for manufacturing a resin-encapsulated electronic component) in Example 1.

FIG. 3 is a cross sectional view schematically showing a step of the method of manufacturing a resin-encapsulated electronic component using the manufacturing apparatus of FIG. 2.

FIG. 4 is a cross sectional view schematically showing another step of the method of manufacturing a resin-encapsulated electronic component using the manufacturing apparatus of FIG. 2.

FIG. 5 is a cross sectional view schematically showing yet another step of the method of manufacturing a resin-encapsulated electronic component using the manufacturing apparatus of FIG. 2.

FIG. 6 is a cross sectional view schematically showing still another step of the method of manufacturing a resin-encapsulated electronic component using the manufacturing apparatus of FIG. 2.

FIGS. 7 (a) to (h) are cross sectional views schematically showing the resin placement step, the transfer step, and steps before and after these steps in Example 2.

FIG. 8 is a cross sectional view schematically showing a part of the manufacturing apparatus (apparatus for manufacturing a resin-encapsulated electronic component) in Example 2.

FIG. 9 is a cross sectional view schematically showing a step of the method of manufacturing a resin-encapsulated electronic component using the manufacturing apparatus of FIG. 8.

FIG. 10 is a cross sectional view schematically showing another step of the method of manufacturing a resin-encapsulated electronic component using the manufacturing apparatus of FIG. 8.

FIG. 11 is a cross sectional view schematically showing yet another step of the method of manufacturing a resin-encapsulated electronic component using the manufacturing apparatus of FIG. 8.

FIG. 12 is a cross sectional view schematically showing a variation of the manufacturing apparatus of FIG. 8.

FIG. 13 is a cross sectional view schematically showing a variation of the plate-like member in Example 2 together with the manufacturing apparatus.

FIG. 14 is a cross sectional view schematically showing another variation of the plate-like member in Example 2 together with the manufacturing apparatus.

FIG. 15 is a cross sectional view schematically showing yet another variation of the plate-like member in Example 2 together with the manufacturing apparatus.

FIG. 16 is a cross sectional view schematically showing still another variation of the plate-like member in Example 2 together with the manufacturing apparatus.

FIG. 17A is a cross sectional view schematically showing an example of each of the members for manufacturing a resin-encapsulated electronic component in the case where the number of electronic components is one.

FIG. 17B is a cross sectional view schematically showing an example of each of the members for manufacturing a resin-encapsulated electronic component in the case where the number of electronic components is more than one.

FIG. 18 is a cross sectional view schematically showing an example in which plate-like members are fixed on a release film with adhesives.

### DESCRIPTION OF EMBODIMENTS

Next, the present invention will be described in more detail. However, the present invention is not limited to the following description.

In the manufacturing method of the present invention, while there is no particular limitation on the plate-like member, the plate-like member is preferably a heat-releasing plate (heat sink) or a shield (blocking plate). The shield may be the one that blocks electromagnetic waves emitted from the electronic component, for example. Further, there is no particular limitation on the shape of the plate-like member. For example, in a case where the plate-like member is a heat-releasing plate, the heat-releasing plate may have, for example, the shape of a fin in which one or more protrusions are bound to a main body of the plate-like member for improving heat-releasing efficiency. While there is no particular limitation on the material of the plate-like member, in a case where the plate-like member is a heat-releasing plate or a shield, for example, metal or the like can be used. Note here that, the plate-like member is also a functional member (action member) having some kind of functions. For example, in a case where the plate-like member is a heat-releasing plate (heat sink), the plate-like member is a functional member (action member) having a heat-releasing function (heat-releasing action) and in a case where the plate-like member is a shield (blocking plate), the plate-like member is a functional member (action member) having a blocking function (blocking action).

During transferring the resin, the resin may be transferred into a die cavity of the molding die in a state where the plate-like member on which the resin is placed is placed on a release film. Further, for example, the plate-like member may be fixed on the release film with an adhesive.

As described above, while there is no particular limitation on the shape of the plate-like member, for example, the plate-like member may include a resin containing portion. Further, with respect to the manufacturing method of the present invention, during placing the resin, the resin may be placed in the resin containing portion of the plate-like member and the transfer of the resin and the compression molding may be performed in a state where the resin is placed in the resin containing portion.

In the manufacturing method of the present invention, there is no particular limitation on the resin, and for example, the resin may either be a thermoplastic resin or a thermosetting resin. The resin may be at least one selected from the group consisting of granular resins, powdery resins, liquid resins, plate-like resins, sheet-like resins, film-like resins, and paste-like resins, for example. Further, the resin may be at least one selected from the group consisting of transparent resins, translucent resins, and opaque resins, for example.

In the manufacturing apparatus of the present invention, the transfer unit may be the one that transfers the resin into a die cavity of the molding die in a state where the plate-like member on which the resin is placed is placed on a release film. In this case, the resin-encapsulation unit may include a release film attractive unit and may perform the compression molding in a state where the release film is attracted by the release film attractive means. Further, in the present invention, there is no particular limitation on the molding die, and examples thereof include a metal die and a ceramic die.

### EXAMPLES

Hereinafter, specific Examples of the present invention will be described with reference to Figures. Each Figure is schematically illustrated by appropriately omitting, exaggerating, and the like for convenience in explanation.

### Example 1

In this Example, the method of manufacturing a resin-encapsulated electronic component and the apparatus for manufacturing a resin-encapsulated electronic component that use the release film will be described.

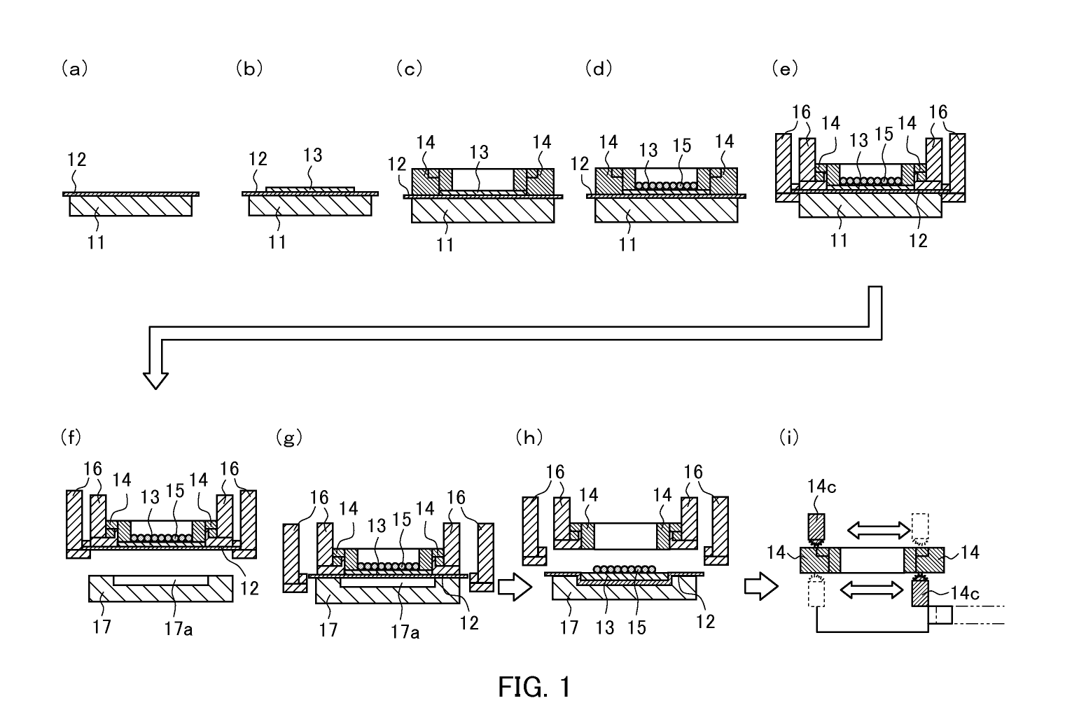

In the cross sectional views of FIGS. 1 (a) to (i), the resin placement, the transfer of the resin, and procedures before and after these steps in this Example are schematically shown.

First, as shown in FIG. 1 (a), a release film 12 is affixed to a XY table 11. The XY table 11 may be, for example, an attractive table that is able to attract the release film 12. For example, a hollow may be provided in the inside of the XY table 11 and a groove or a pore coupled with the hollow may be provided on an attractive surface of the release film, and the release film 12 may be attracted by the groove or the pore by reducing the pressure in the inside of the XY table 11. Alternatively, for example, the release film 12 may be affixed by affixing a part of a long release film to the XY table 11 and cutting the release film to leave only a part that will be required for the following steps.

Next, as shown in FIG. 1 (b), a heat-releasing plate (heat sink) 13 is placed on the center of the release film 12. The heat-releasing plate 13 corresponds to the “plate-like member” in the manufacturing method of the present invention. Further, as shown in FIG. 1 (c), a tray cover 14 is placed on the affixed release film 12 so that the release film 12 is interposed between the XY table 11 and the tray cover 14. As shown in FIG. 1 (c), the outer edge portion of the heat-releasing plate 13 and a part of the release film 12, which is placed further outer side of the heat-releasing plate 13, are covered with the tray cover 14 but the center of the heat-releasing plate 13 is not covered with the tray cover 14.

Next, as shown in FIG. 1 (d), a resin 15 is placed on the part of the heat-releasing plate 13 that is not covered with the tray cover 14. Thereby, as shown in FIG. 1 (d), the resin 15 is enclosed by the tray cover 14. FIG. 1 (d) illustrates the placing of the resin of the manufacturing method of the present invention.

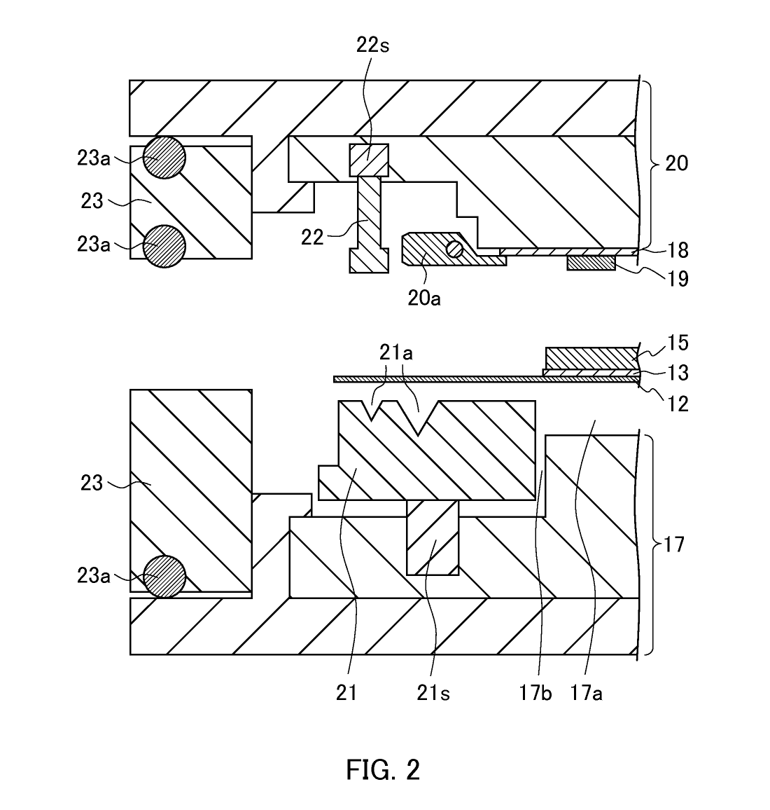

Next, as shown in FIG. 1 (e), the release film 12 is held by a resin handler 16 together with the heat-releasing plate 13 placed on the release film 12, the resin 15, and the tray cover 14. The resin handler 16 includes parts that sandwich the tray cover 14 and the heat-releasing plate 13 from the lateral sides to hold them and parts that sandwich the outer edge portion of the release film 12 from the upper and lower sides to hold it. Note here that, the resin handler 16 corresponds to the transfer unit of the manufacturing apparatus of the present invention. Then, as shown in FIG. 1 (f), the heat-releasing plate 13 and the resin 15 are transferred to the position above a lower die cavity 17a of a lower die 17 by the resin handler 16 in a state where the heat-releasing plate 13 and the resin 15 are placed on the release film 12 and the tray cover 14. Further, as shown in FIG. 1 (g), the release film 12, the heat-releasing plate 13, the resin 15, and the tray cover 14 are released from the hold by the resin handler 16 and are passed to the lower die 17. Thereby, as shown in FIG. 1 (h), the resin 15 is placed on the cavity surface (position of the die cavity) of the lower die cavity 17a in a state where the resin 15 is placed on the heat-releasing plate 13. In other words, FIGS. 1 (e) to (h) illustrate the transferring of the resin of the manufacturing method of the present invention. After the procedure shown in FIG. 1 (h), the resin-encapsulation is performed using the lower die 17. This will be described separately with reference to FIGS. 2 to 6. On the other hand, after the procedure shown in FIG. 1 (h), only the tray cover 14 is transferred to a cleaning stage by the resin handler 16. Then, as shown in FIG. 1 (i), in the cleaning stage, the top surface and under surface of the tray cover 14 are cleaned with cleaners 14c. Thereafter, using a new release film, a new heat-releasing plate, and a new resin, the procedures shown in FIGS. 1 (a) to (h) are repeated.

Note here that, in the manufacturing method of the present invention, while there is no particular limitation on the molding die for compression molding (for example, compression molding die), for example, the molding die may be formed of an upper die and a lower die. While FIG. 1 only shows the lower die 17 as a molding die, the molding die in this Example is formed of the lower die 17 and an upper die 20 as shown in FIGS. 2 to 6. Further, in the present invention, for example, the “die cavity” may be formed only in a lower die or in an upper die, or a cavity may be formed in each of the lower die and the upper die and the “die cavity” may be the combination of a lower die cavity and an upper die cavity. In the manufacturing method of the present invention, the transferring of the resin, as described above, includes transferring the resin to the position of the die cavity of the molding die in a state where the resin is placed on the plate-like member. With reference to the “transferring the resin to the position of the die cavity of the molding die”, for example, as shown in FIG. 1 (h), the resin may be placed on the cavity surface of the lower die. Further, for example, in a case where a die cavity is formed only in an upper die, the resin may be placed on the part of the lower die corresponding to the position of the upper die cavity.

Next, with reference to schematic cross sectional views of FIGS. 2 to 6, the manufacturing method of this Example including the resin-encapsulation will be described in more detail. Also, the manufacturing apparatus used for the manufacturing method will be described. In FIGS. 2 to 6, identical parts to those shown in FIG. 1 are indicated with identical numerals and symbols. However, for convenience in illustration, the shapes and the like of some of them may be shown differently from FIG. 1.

First, the cross sectional view of FIG. 2 schematically shows a part of the manufacturing apparatus (apparatus for manufacturing a resin-encapsulated electronic component) in this Example. This manufacturing apparatus includes a resin placement unit, a molding die including a die cavity, a transfer unit, and a resin-encapsulation unit as main components. The resin placement means, which is not shown, places the resin 15 on the heat-releasing plate 13 in FIG. 1 (d). The molding die is, as shown in FIG. 2, formed of a lower die 17 and an upper die 20 and includes a lower die cavity (die cavity) 17a. The transfer unit, which is not shown in FIG. 2, is the resin handler 16 shown in FIG. 1.

The resin-encapsulation unit is a component of this manufacturing apparatus and includes all the components shown in FIG. 2 including the molding die (the lower die 17 and the upper die 20). In other words, as shown in FIG. 2, the resin-encapsulation unit includes the lower die 17, the upper die 20, a clamper 20a, a film retainer 22, and a FM (fine mold) cover 23 as main components. As shown in FIG. 2. the lower die 17 includes a lower die chase holder, which is an outside (lower side) member, a lower die chase attached on the inside (upper side) of the lower die chase holder, and a lower die outer circumferential end retainer 21. The lower die outer circumferential end retainer 21 is attached on the lower die chase with a spring 21s and also is serving as an outer edge portion of the lower die 17. There is a void 17b between the lower die outer circumferential end retainer 21 and the lower die chase. Further, release film attractive grooves 21a are provided at the top surface of the lower die outer circumferential end retainer 21. The upper die 20 includes an upper die chase holder, which is an outside (upper side) member, and an upper die chase attached on the inside (lower side) of the upper die chase holder. A clamper 20a is attached on the upper die chase and is able to fix a substrate 18 for a resin-encapsulated electronic component to the die surface (under surface) of the upper die chase as shown in FIG. 2. A film retainer 22 is attached on the outer edge portion of the upper die chase with a spring 22s and is able to fix the release film 12 by sandwiching it together with the lower die outer circumferential end retainer 21 from the upper and lower sides. A FM cover (outside air blocking member) 23 is attached on each of the outer edge portions of the upper die chase holder and the lower die chase holder (the outsides of the upper die chase and the lower die chase). Further, an elastic O ring 23a is provided at each of the spaces between the upper die chase holder and the upper FM cover 23, between the upper FM cover 23 and the lower FM cover 23, and between the lower FM cover 23 and the lower die chase holder.

As will be described later, the resin-encapsulation unit performs resin-encapsulation of an electronic component 19 by subjecting the resin 15 to compression molding together with the plate-like member 13 and the electronic component 19 in a state where the electronic component 19 is soaked in the resin 15 placed on the heat-releasing plate (plate-like member) 13 in the lower die cavity (die cavity) 17a. Note here that, in FIG. 2, the release film 12, the heat-releasing plate 13, the resin 15, the substrate 18, and the electronic component 19 are not the components of the manufacturing apparatus.

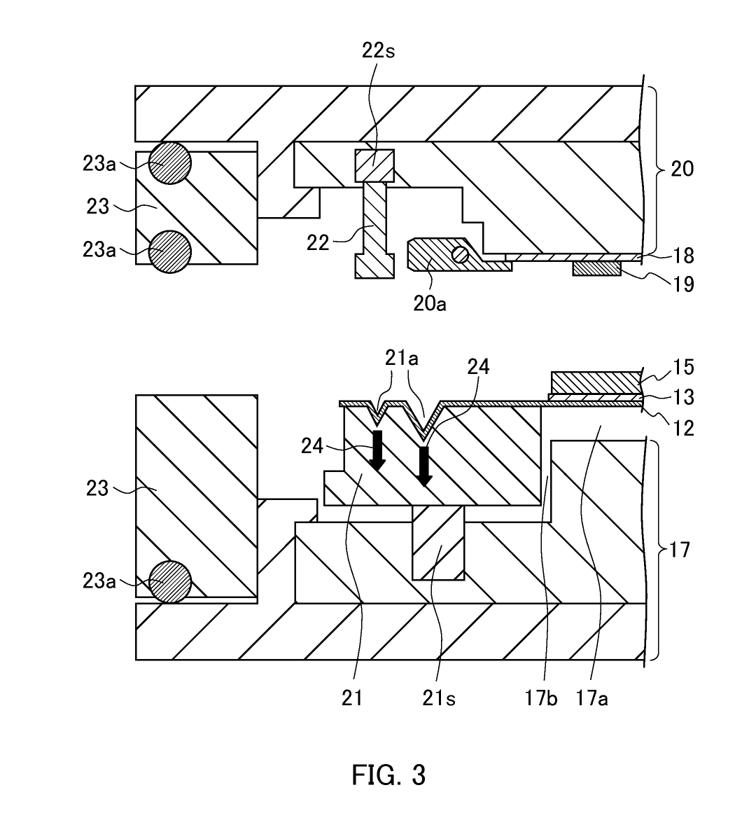

Next, the method of manufacturing a resin-encapsulated electronic component using this manufacturing apparatus will be described. Note here that, in FIGS. 3 to 6, identical parts to those shown in FIG. 2 are indicated with identical numerals and symbols.

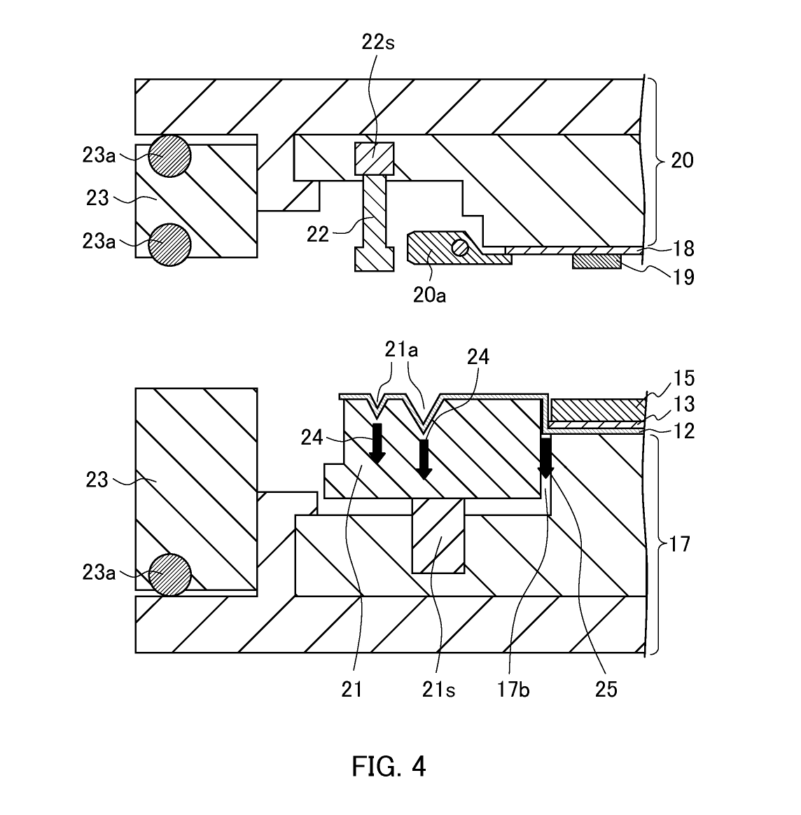

First, as shown in FIGS. 1 (a) to (h), placing the resin 15 on the heat-releasing plate 13 and transferring the resin 15 to the position of the lower die cavity 17a in a state where the resin 15 is placed on the heat-releasing plate 13 are performed. In transferring the resin, the procedures shown in FIGS. 1 (f) to (h) will be described in more detail with reference to FIGS. 2 to 4. In other words, FIG. 2 shows the details of the procedure shown in FIG. 1 (f), FIG. 3 shows the details of the procedure shown in FIG. 1 (g), and FIG. 4 shows the details of the procedure shown in FIG. 1 (h). Note here that, in FIGS. 2 to 4, for convenience in illustration, the tray cover 14 and the resin handler 16 are not shown.

First, as shown in FIG. 2, the heat-releasing plate 13 and the resin 15 are transferred to the position above the lower die cavity 17a in a state where the heat-releasing plate 13 and the resin 15 are placed on the release film 12. At this time, as shown in FIG. 2, the substrate 18 for resin-encapsulated electronic component is fixed on the under surface (die surface) of the upper die chase of the upper die 20 with the clamper 20a. The electronic component 19 is attached on the under surface of the substrate 18 such that the electronic component 19 faces the resin 15. Note here that, the substrate 18 is transferred separately and fixed to the under surface (die surface) of the upper die chase.

Next, as shown in FIG. 3, the release film 12, the heat-releasing plate 13, and the resin 15 are passed to the lower die 17, and as indicated by arrows 24, the pressure inside of the lower die outer circumferential end retainer 21 is reduced with a vacuum pump (not shown) to cause the release film 12 to be attracted by the release film attractive grooves 21a. Thereby, the release film 12 placed on the lower die cavity 17a is under tension.

Further, as indicated by an arrow 25 in FIG. 4, the pressure in the void 17b between the lower die outer circumferential end retainer 21 and the lower die chase is reduced with a vacuum pump (not shown) to cause the release film 12 to be attracted by the cavity surface of the lower die cavity 17a. Thereby, as shown in FIG. 4, the resin 15 is placed on the cavity surface (position of the die cavity) of the lower die cavity 17a in a state where the resin 15 is placed on the heat-releasing plate 13.

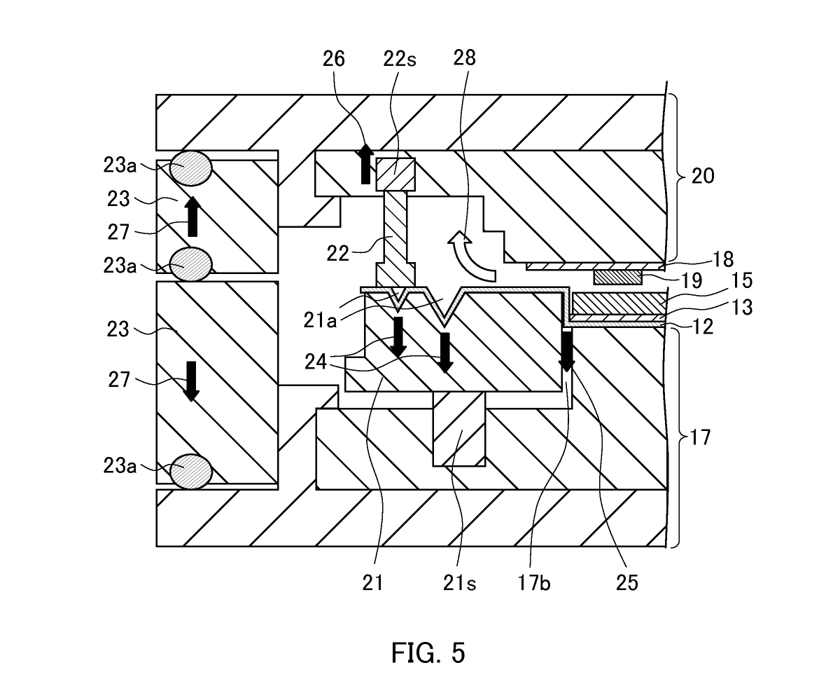

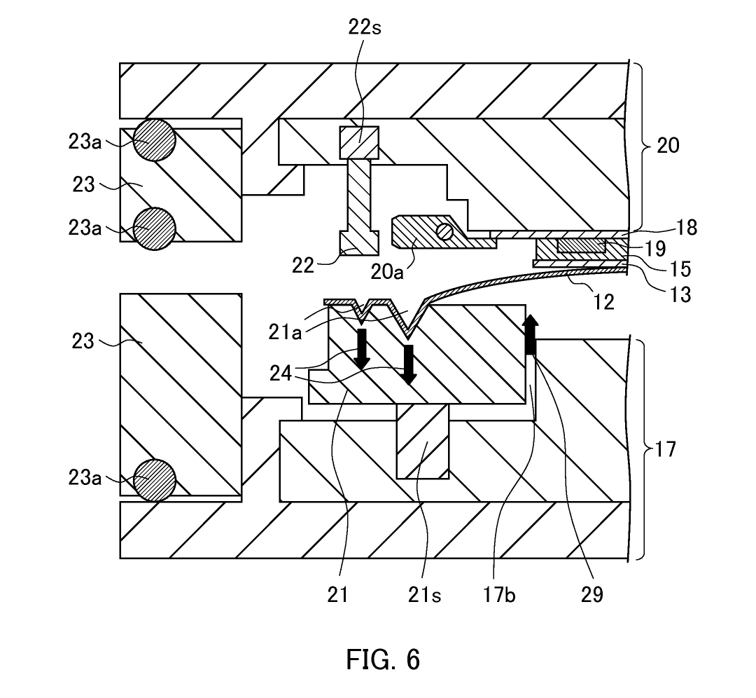

Next, as shown in FIGS. 5 to 6, the resin-encapsulation is performed. Note here that, in FIG. 5, for the sake of convenience, the clamper 20a is not shown.

That is, first, as shown in FIG. 5, the lower die 17 is lifted up together with the FM cover 23, and the release film 12 is sandwiched by the lower die outer circumferential end retainer 21 and the film retainer 22 to hold it. At this time, as indicated by an arrow 26, the force of the film retainer 22 acts on the spring 22 to press it upward and the reaction thereof acts as a force to fix the release film 12. In contrast, The force of the lower die outer circumferential end retainer 21 acts on the spring 21s to press it downward and the reaction thereof acts as a force to fix the release film 12. Then, the lower die 17 is further lifted up to the starting position of compression molding, and the electronic component 19 is soaked in the resin 15 in the lower die cavity 17a. At this time, the resin 15 is in a state of having fluidity. Further, at this time, there may be a slight clearance (void) between the substrate 18 and the release film 12. Thereby, as shown by arrows 27, the forces act on O rings 23a to press them upward and downward, and the airtightness between the upper die chase holder and the lower die chase holder (hereinafter, this will be referred to as “inside of the chase holder”) is maintained. Then, as indicated by an arrow 28, the pressure in the inside of the chase holder (at least inside the lower die cavity 17a) is reduced with a vacuum pump and a FM suction valve (not shown). In this state, the resin-encapsulation of electronic component 19 is performed by subjecting the resin 15 to compression molding together with the heat-releasing plate 13, the electronic component 19, and the substrate 18. In this manner, the resin encapsulation is performed and the resin-encapsulated electronic component formed of the substrate 18, the electronic component 19, and the resin 15 can be manufactured.

Note here that, as described above, at the time of soaking the electronic component 19 in the resin 15 in the lower die cavity 17a, the resin 15 is in a state of having fluidity. This resin 15 having fluidity may be, for example, liquid resins (pre-hardened thermosetting resins and the like) or molten resins obtained by heating and melting solid resins such as granular resins, powdery resins, paste-like resins, and the like. The heating of the resin 15 can be performed by heating the lower die 17, for example. Further, for example, in a case where the resin 15 is a thermosetting resin, the resin 15 may be thermally hardened by pressurizing the resin 15 in the lower die cavity 17a. Thereby, resin-encapsulation molding (compression molding) of the electronic component 19 can be performed in the resin forming body (package) corresponding to the shape of the lower die cavity 17a. This makes it also possible to perform molding in a state where the plate-like member 13 is exposed at the top surface (the opposite side of the substrate) of the resin forming body (package), for example.

After the compression molding (resin-encapsulation), as shown in FIG. 6, the lower die 17 is brought down, and the inside of the chase holder is opened to release the depressurization. Thereby, at the same time, as indicated by an arrow 29, the depressurization in the void 17b between the lower die outer circumferential end retainer 21 and the lower die chase is released. On the other hand, the release film 12 is kept being attracted by the release film attractive grooves 21a of the top surface of the lower die outer circumferential end retainer 21, and the substrate 18 is kept being fixed on the under surface (die surface) of the upper die chase with the clamper 20a. Then, since the resin 15 and the heat-releasing plate 13 are subjected to compression molding together with the substrate 18 and the electronic component 19, the downward movement of the lower die 17 causes the release film 12 to be peeled off the resin-encapsulated electronic component formed of the substrate 18, the electronic component 19, and the resin 15. The resin-encapsulated electronic component can be transferred to the outside of the apparatus shown in FIG. 2 by another transfer means (not shown).

Note here that the “FM (fine molding)” of performing the compression molding by reducing the pressure in the inside of the chase holder (at least the inside of the die cavity) is employed in this Example. However, the present invention is not limited thereto and other ways of compression molding can be employed.

Further, 13 can be a plate-like member other than the heat-releasing plate, and may be, for example, a blocking plate (shield).

Further, while the manufacturing method of the present invention includes the resin placement, the transfer of the resin, and the resin-encapsulation as described above, the manufacturing method of the present invention may include any other procedures as shown in this Example.

In this Example, as described above, the resin is transferred into the die cavity of the molding die in a state where the plate-like member on which the resin is placed is placed on the release film. Thereby, for example, in FIGS. 2 to 6, the contact of the resin 15 with the lower die 17 and the entry of the resin 15 into the void 17b of the lower die 17 can be prevented. Also, the structures of the plate-like member and the transfer unit thereof are easy to be simplified.

### Example 2

Next, another Example of the present invention will be described.

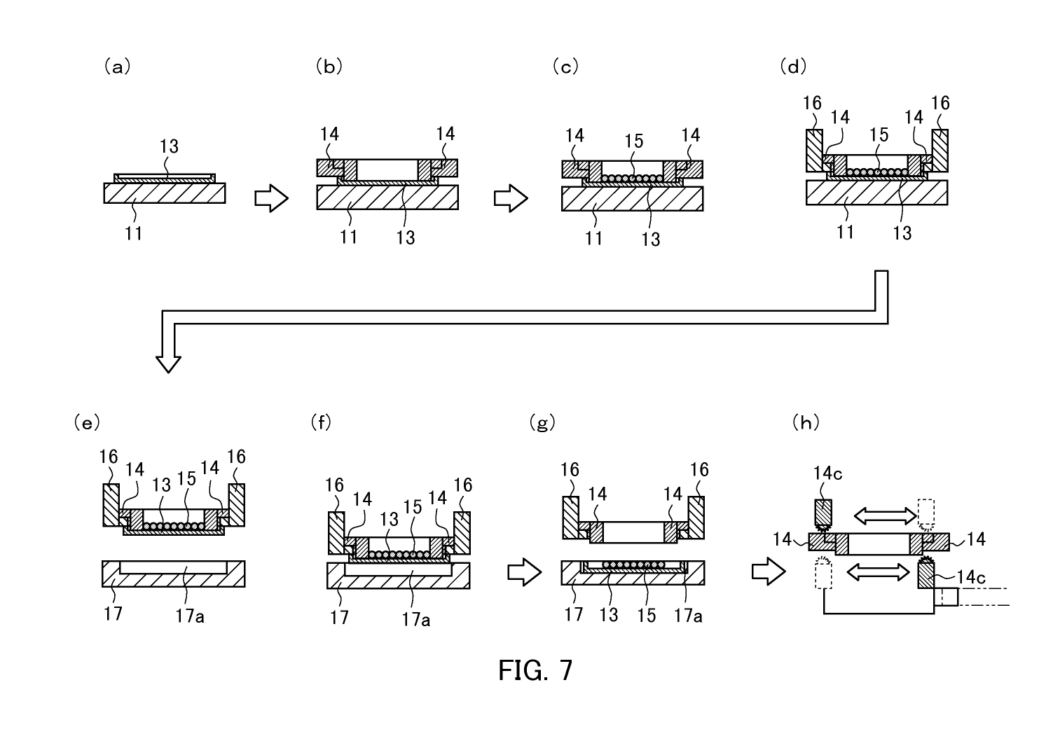

In the cross sectional views of FIGS. 7 (a) to (h), the resin placement, the transfer of the resin, and procedures before and after these procedures in this Example are schematically shown. In this Example, a heat-releasing plate 13 includes a resin containing portion. More specifically, as shown in FIGS. 7 (a) to (h), the heat-releasing plate 13 of this Example has a tray shape in which the outer edge portions are vertically raised so that the center of the heat-releasing plate 13 serves as a resin containing portion. In this Example, the resin 15 is placed in the resin containing portion, and the transfer of the resin and the compression molding are performed in a state where the resin 15 is placed in the resin containing portion. Further, in this Example, a release film 12 is not used. A resin handler 16 includes parts that sandwich a tray cover 14 and the heat-releasing plate 13 from the lateral sides to hold them but does not include parts to hold the release film 12.

Since the release film 12 is not used in this Example, the step shown in FIG. 1 (a) is omitted. FIGS. 7 (a) to (h) are the same as FIGS. 1 (b) to (i) except that the release film 12 is not used, the shape of the heat-releasing plate 13 is different, and the structure of the resin handler 16 is different.

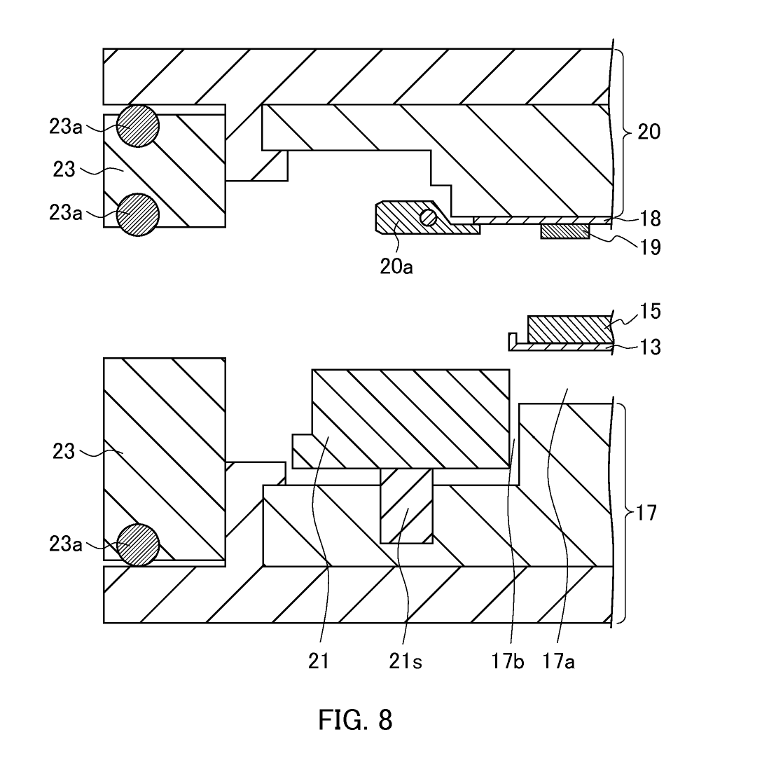

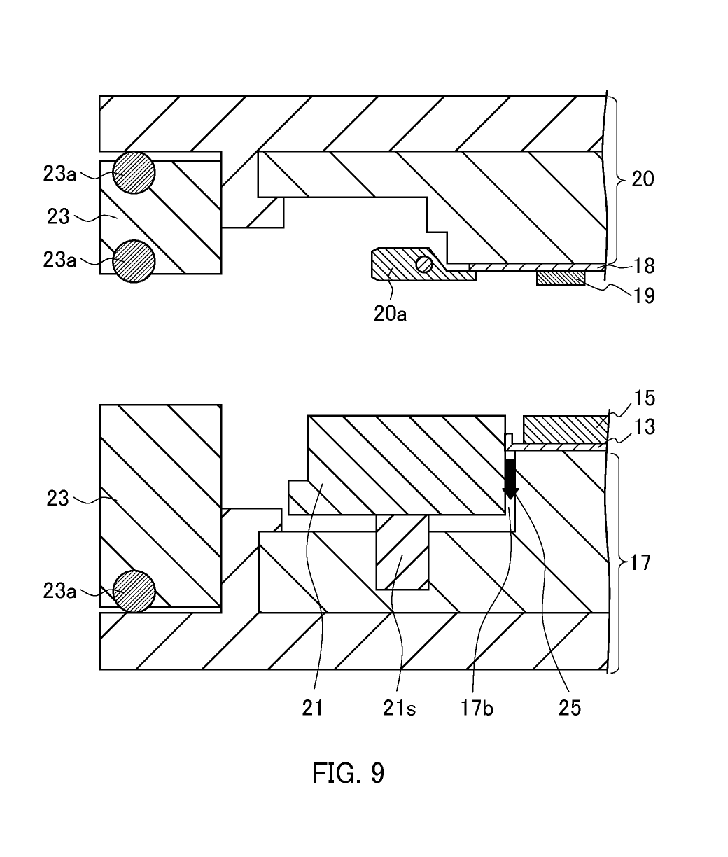

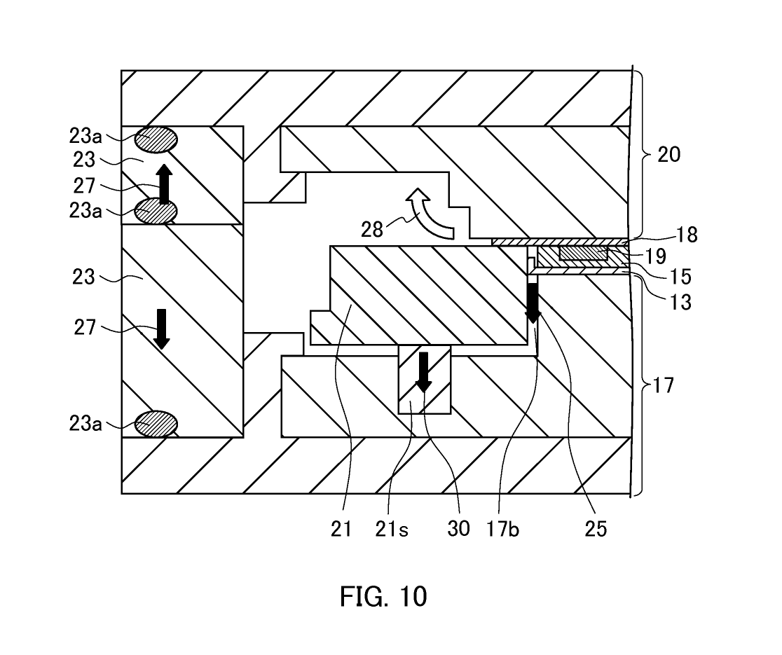

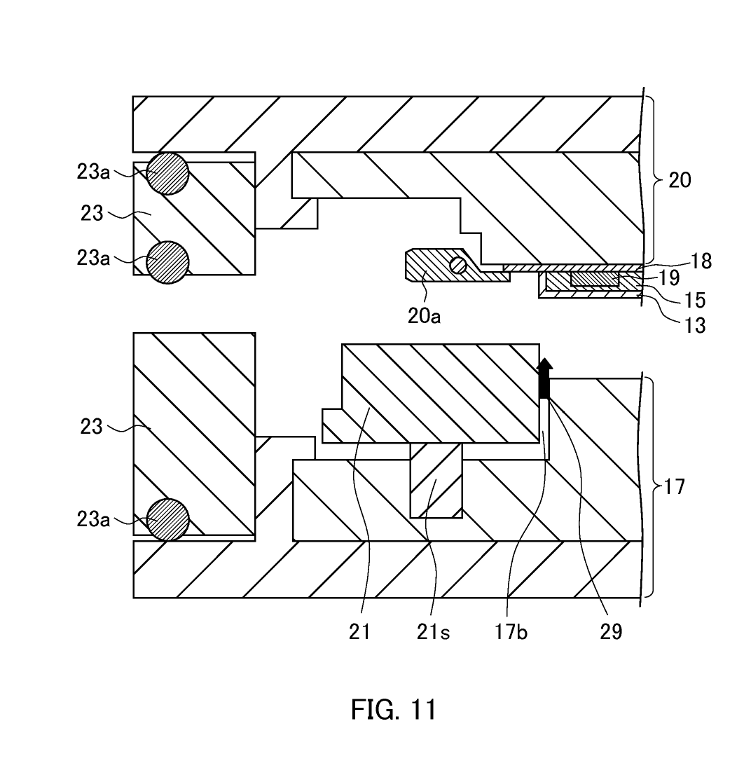

Also, the manufacturing method and the manufacturing apparatus schematically shown in cross sectional views of FIGS. 8 to 11 are the same as those shown in FIGS. 2 and 4 to 6 of Example 1 except that the release film 12 is not used, the release film attractive groove 21a, the film retainer 22, and the spring 22s are not provided, and the shape of the heat-releasing plate 13 is different. Since the release film 12 is not used, the procedure shown in FIG. 3 of causing the release film to be attracted by the release film attractive grooves 21a is omitted. Note here that a downward arrow 30 in FIG. 10 indicates the direction of the force acting on the spring 21s.

In this Example, since the outer edge portions of the heat-releasing plate 13 are raised so that the center of the heat-releasing plate 13 serves as a resin containing portion, the contact of the resin 15 with the lower die 17 and the entry of the resin 15 into the void 17b between the lower die outer circumferential end retainer 21 and the lower die chase can be restricted or prevented without using the release film 12. Therefore, as well as the cost saving by omitting the release film, the manufacturing efficiency of the resin-encapsulated electronic component can be increased because the steps of affixing or attracting the release film can be omitted.

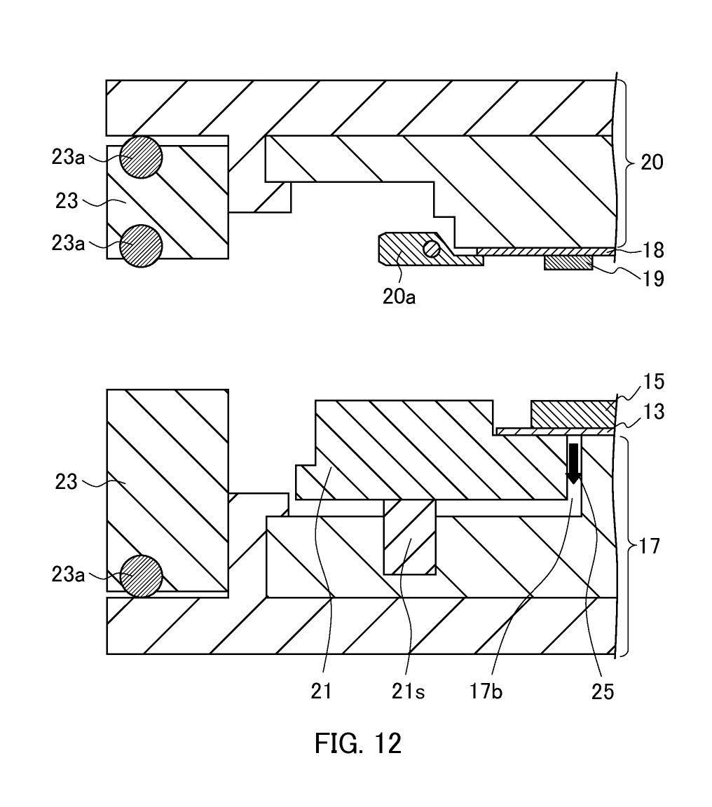

Note here that the shape and the structure of the plate-like member such as a heat-releasing plate and the like are not limited to those shown in FIGS. 7 to 11 and various shapes and structures can be employed. The examples thereof are shown in FIGS. 12 to 16. These are the examples of the manufacturing method and the manufacturing apparatus in which the release film is not used.

FIG. 12 shows an example in which the heat-releasing plate 13 has a flat plate shape. In FIG. 12, the lower die outer circumferential end retainer 21 includes a step, and the outer edge portion of the heat-releasing plate 13 can be placed on the lower part of the step. Thereby, even when the heat-releasing plate 13 has a flat plate shape and the release film is not used, the contact of the resin 15 with the lower die 17 and the entry of the resin 15 into the void 17b between the lower die outer circumferential end retainer 21 and the lower die chase can be restricted or prevented.

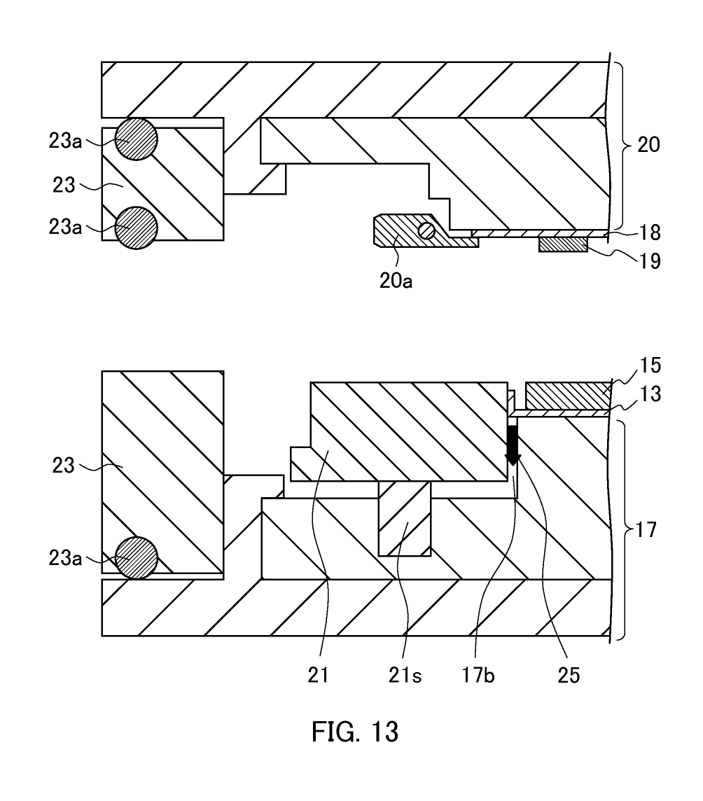

FIG. 13 shows an example in which the outer edge portions of the heat-releasing plate 13 are raised so that the center of the heat-releasing plate 13 serves as the resin containing portion as in the examples shown in FIGS. 7 to 11.

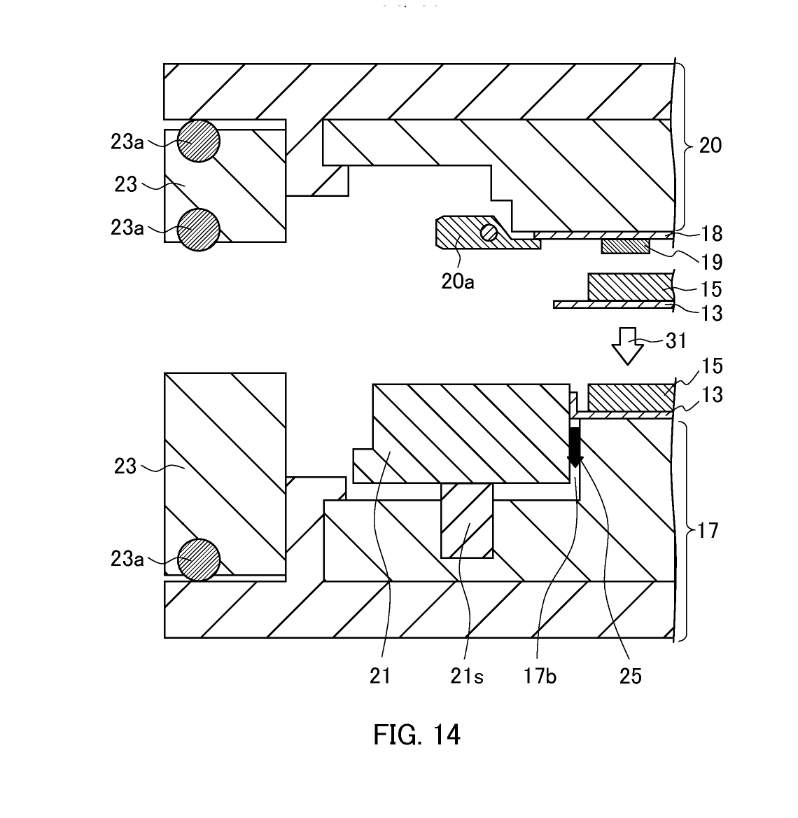

FIG. 14 shows an example in which the heat-releasing plate 13 has a flat plate shape. The structure of the manufacturing apparatus is the same as that shown in FIGS. 8 to 11. In FIG. 14, as indicated by an arrow 31, by performing press molding of the heat-releasing plate 13 with the lower die 17, the upper die 20, and the lower die outer circumferential end retainer 21 at the time of compression molding, like the heat-releasing plate 13 shown in FIGS. 8 to 11, the heat-releasing plate 13 of this example can take a tray shape in which the outer edge portions are raised so that the center of the heat-releasing plate 13 serves as a resin containing portion. Thereby, as in the examples shown in FIGS. 8 to 11, the contact of the resin 15 with the lower die 17 and the entry of the resin 15 into the void 17b between the lower die outer circumferential end retainer 21 and the lower die chase can be restricted or prevented.

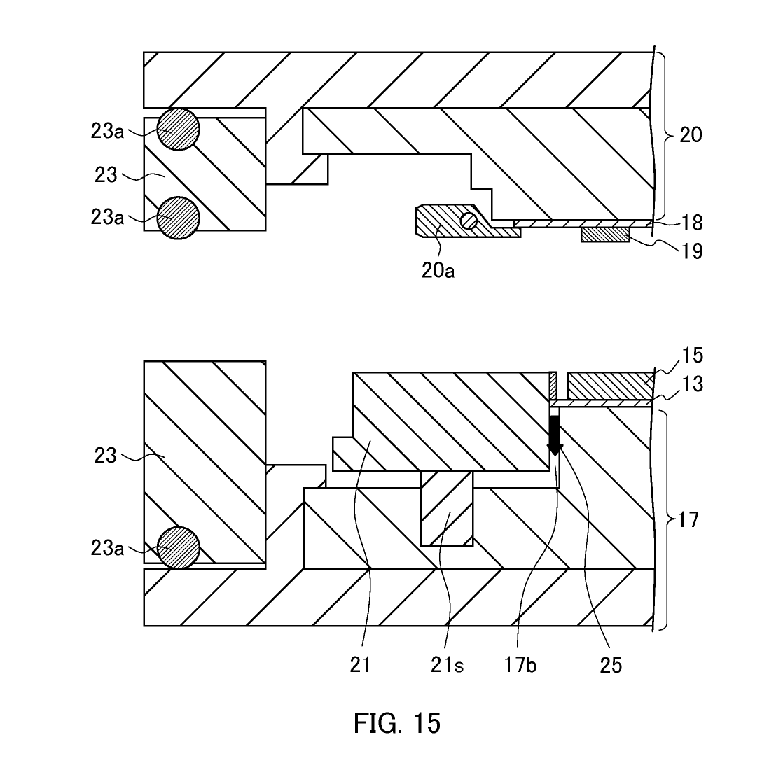

FIG. 15 shows an example in which the material of the raised part of the outer edge portion (external wall) of the heat-releasing plate 13 is different from that of the main body (flat plate part) of the heat-releasing plate. For example, the main body of the heat-releasing plate may be made of metal and the raised part of the outer edge portion (external wall) of the heat-releasing plate may be made of a heat-resistant resin. Except for this, the example shown in FIG. 15 is the same as the examples shown in FIGS. 8 to 11.

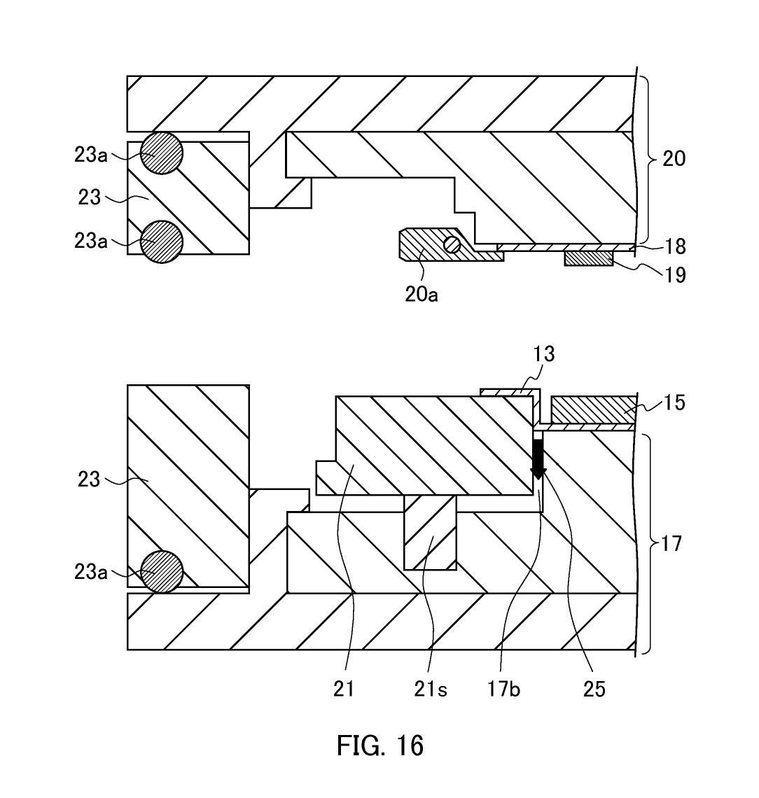

FIG. 16 shows an example in which the upper part of the raised part of the outer edge portion of the heat-releasing plate 13 is horizontally protruded toward the outside of the heat-releasing plate 13, and the protruded part can be placed on the lower die outer circumferential end retainer 21. Thereby, the contact of the resin 15 with the lower die 17 and the entry of the resin 15 into the void 17b between the lower die outer circumferential end retainer 21 and the lower die chase can be restricted or prevented more effectively. Except for this, the example shown in FIG. 16 is the same as the examples shown in FIGS. 8 to 11.

Further, in this Example, as in Example 1, 13 can be a plate-like member other than the heat-releasing plate, and may be, for example, a blocking plate (shield).

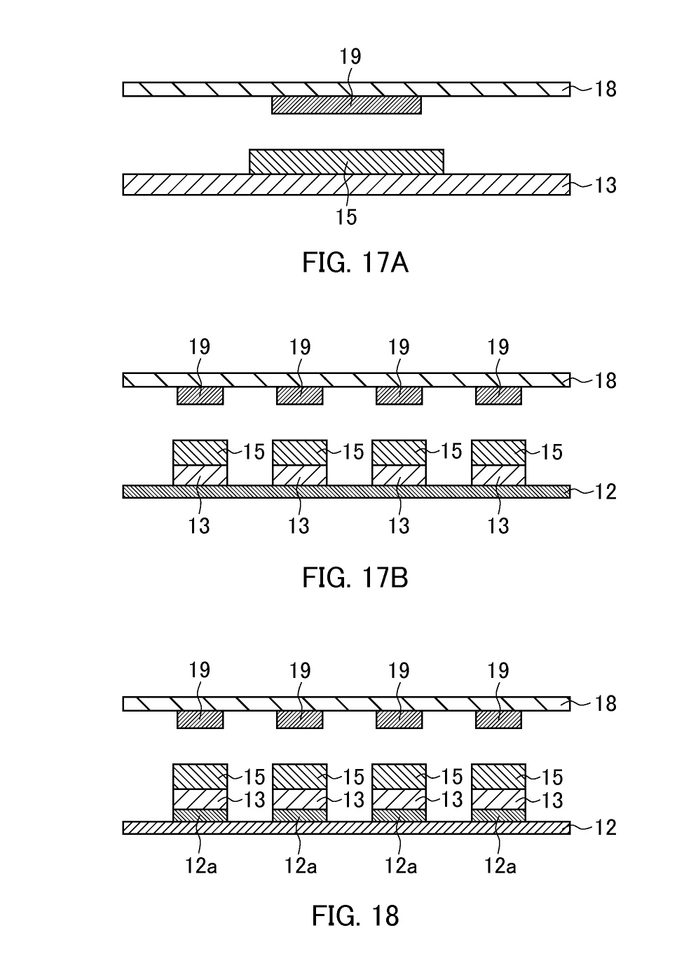

Note here that, with respect to the resin-encapsulated electronic component manufactured by the present invention, for example, the number of the electronic components may be one or more than one. In the cross sectional view of FIG. 17A, an example of each of the members for manufacturing the resin-encapsulated electronic component in the case where the number of the electronic components is one is schematically shown. As shown in FIG. 17A, the members include the substrate 18 and the plate-like member (for example, heat-releasing plate, shield, or the like) 13. An electronic component 19 is fixed on the one side of the substrate 18 and the resin 15 is placed on the one side of the plate-like member 13. The resin-encapsulated electronic component is manufactured by placing the electronic component 19 and the resin 15 so as to face each other as shown in FIG. 17A and encapsulating the electronic component 19 with the resin 15 in the manner described in Example 1 or 2, for example.

In the cross sectional view of FIG. 17B, an example of each of the members for manufacturing the resin-encapsulated electronic component in the case where the number of the electronic components is more than one is schematically shown. The members are the same as those shown in FIG. 17A except that a plurality of electronic components 19 are fixed on the substrate 18, the number of each of the plate-like members 13 and the resins 15 is the same as the number of the electronic components 19, and the plate-like members 13 are placed on the release film 12. Although the resin-encapsulated electronic component can be manufactured without the release film 12, in the case where the plate-like member 13 and the resin 15 are more than one, the plate-like members 13 and the resins 15 are preferably placed and handled on the release film 12 as shown in FIG. 17B for the sake of convenience. In this case, for example, the resin-encapsulated electronic component can be manufactured in the same manner as in Example 1 in which the release film 12 is used.

Further, as described above, in the present invention, the plate-like member may be fixed on the release film with an adhesive. An example thereof is schematically shown in the cross sectional view of FIG. 18. The example shown in FIG. 18 is the same as the example shown in FIG. 17B except that a plurality of micro regions (weak adhesives) of the adhesives 12a are provided on the release film 12 and the plate-like members 13 are fixed on the release film 12 with weak adhesives 12a. While the method of fixing the plate-like member on the release film with an adhesive can be used for the manufacture of the resin-encapsulated electronic component in which the number of the electronic component is one, for example, the method is preferably used for the manufacture of the resin-encapsulated electronic component in which the number of the electronic components is more than one as in the example shown in FIG. 18. Thereby, the entry of the resin 15 into the space between the plate-like member 13 and the release film 12 can be prevented.

The present invention is not limited to the aforementioned Examples; and arbitrary and suitable combinations, changes, or selective adoption thereof can be made as necessary without departing from the spirit and scope of the present invention.

### EXPLANATION OF REFERENCE NUMERALS

11 XY table
12 release film
13 heat-releasing plate (plate-like member)
14 tray cover
14c cleaner
15 resin
16 resin handler
17 lower die
17a lower die cavity (die cavity)
17b void
18 substrate
19 electronic component
20 upper die
21 lower die outer circumferential end retainer
22 film retainer
21s, 22s spring
23 FM cover
23a O ring
24, 25 attraction by depressurization
26, 30 direction of force acting on spring
27 direction of force acting on FM cover
28 depressurization of inside of chase holder
29 release of depressurization
31 transferring direction of heat-releasing plate 13

1. A method of manufacturing a resin-encapsulated electronic component, the resin-encapsulated electronic component comprising a plate-like member, the method comprising:
placing a resin on the plate-like member;
transferring the resin to a position of a die cavity of a molding die in a state where the resin is placed on the plate-like member; and
performing resin-encapsulation of an electronic component by subjecting the resin to compression molding together with the plate-like member and the electronic component in a state where the electronic component is soaked in the resin placed on the plate-like member in the die cavity.

2. The method according to claim 1, wherein
the plate-like member comprises a heat-releasing plate or a shield.

3. The method according to claim 1, wherein
during the transferring, the resin is transferred into the die cavity of the molding die in a state where the plate-like member on which the resin is placed is placed on a release film.

4. The method according to claim 3, wherein
the plate-like member is fixed on the release film with an adhesive.

5. The method according to claim 1, wherein
the plate-like member includes a resin containing portion,
during the placing the resin, the resin is placed in the resin containing portion, and
the transferring and the compression molding are performed in a state where the resin is placed in the resin containing portion.

6. The method according to claim 1, wherein
the resin is a thermoplastic resin or a thermosetting resin.

7. The method according to claim 1, wherein
the resin is at least one selected from the group consisting of granular resins, powdery resins, liquid resins, plate-like resins, sheet-like resins, film-like resins, and paste-like resins.

8. The method according to claim 1, wherein
the resin is at least one selected from the group consisting of transparent resins, translucent resins, and opaque resins.

9. An apparatus for manufacturing a resin-encapsulated electronic component, the resin-encapsulated electronic component comprising a plate-like member, the apparatus comprising:
a resin placement unit;
a molding die having a die cavity;
a transfer unit; and
a resin-encapsulation unit, wherein
the resin placement unit places a resin on the plate-like member, the transfer unit transfers the resin to a position of the die cavity in a state where the resin is placed on the plate-like member, and
the resin-encapsulation unit performs resin-encapsulation of an electronic component by subjecting the resin to compression molding together with the plate-like member and the electronic component in a state where the electronic component is soaked in the resin placed on the plate-like member in the die cavity.

10. The apparatus according to claim 9, wherein
the transfer unit transfers the resin into the die cavity of the molding die in a state where the plate-like member on which the resin is placed is placed on a release film.

11. The apparatus according to claim 10, wherein
the resin-encapsulation unit comprises a release film attractive unit, and
the compression molding is performed in a state where the release film is attracted by the release film attractive unit.

12. A plate-like member-equipped release film, comprising
a release film; and
a plate-like member, wherein
the plate-like member is placed on the release film.

13. The plate-like member-equipped release film according to claim 12, wherein
the plate-like member is fixed on the release film with an adhesive.

14. The plate-like member-equipped release film according to claim 12, wherein
the plate-like member comprises a heat-releasing plate and a shield.

15. The plate-like member-equipped release film according to claim 12, wherein
a single plate-like member is placed on a single release film.

16. The plate-like member-equipped release film according to claim 12, wherein
a plurality of plate-like members are placed on a single release film.

17. The plate-like member-equipped release film according to claim 12, wherein
the release film is a long release film.

18. The plate-like member-equipped release film according to claim 12, wherein
the plate-like member-equipped release film is used for the method according to claim 1.
